(19) United States
(12) Patent Application Publication
(10) Pub. No.: US 2010/0245797 A1
(43) Pub. Date: Sep. 30, 2010

(54) Substrate Handling Structure

(75) Inventors: Eric Peter Goodwin, Tucson, AZ (US); Daniel Gene Smith, Tucson, AZ (US); Michael B. Binnard, Belmont, CA (US)

Correspondence Address: LAWRENCE R. OREMLAND, P.C., 5055 E. BROADWAY BLVD., SUITE C-214, TUCSON, AZ, 85711, US

(73) Assignee: Nikon Corporation, Tokyo (JP)

(21) Appl. No.: 12/731,650

(22) Filed: Mar. 25, 2010

Related U.S. Application Data
(60) Provisional application No. 61/211,214, filed on Mar. 26, 2009.

(51) Int. Cl. G03B 27/58; H01L 21/677; B23Q 3/00

(52) U.S. Cl. 355/72; 414/222.01; 269/289 R

(57) ABSTRACT

A substrate handling structure is provided that is particularly useful with an imaging optical system that images a single reticle to a pair of imaging locations. The principles of the present invention provide substrate handling structures with new and useful metrology structures, and new and useful ways of moving substrates in relation to the imaging locations, that are designed to provide benefits in providing information as to the substrate position as a substrate is being imaged, while reducing the size of the support structure. These features are believed to be important as imaging of substrates in the 450 mm diameter range is developing.

### RELATED APPLICATION/CLAIM OF PRIORITY

This application is related to and claims priority from provisional application Ser. No. 61/211,214, filed Mar. 26, 2009, which provisional application is incorporated by reference herein.

### BACKGROUND

The present invention provides improved substrate handling structure, which is particularly useful with an imaging optical system (e.g. a lithographic optical imaging system) that images a single reticle to a pair of imaging locations.

The principles of the substrate handling structure of the present invention are designed to provide for the handling of substrates that are imaged by an imaging optical system whose complexity and size are designed to be as manageable as possible, in a way designed to manage throughput and metrology as one or more substrates are being imaged. These features are believed to be particularly important as imaging of 450 mm diameter substrates (e.g. by lithographic optical imaging systems) is developing.

The principles of the present invention are particularly useful with an imaging optical system known as the Sumo lens, and with an imaging optical system known as the Y Wing lens, each of which is disclosed in U.S. application Ser. No. 12/547,086 (attorney reference 6162.121US), filed Aug. 25, 2009, entitled “High NA Catadioptric Imaging Optics For Imaging a reticle to a Pair of Imaging Locations”, which is incorporated by reference herein). Each of the Sumo and Y Wing lens is designed to simultaneously image a single reticle to a pair of imaging locations for simultaneously imaging substrates at those imaging locations.

### SUMMARY OF THE PRESENT INVENTION

The present invention provides new and useful substrate handling structures that is particularly useful with lithographic optical imaging systems, such as the types of lithographic imaging optical systems shown in U.S. application Ser. No. 12/547,086, filed Aug. 25, 2009, which has been incorporated by reference herein.

In one of its basic aspects, the present invention provides new and useful ways of moving substrates to and from a pair of imaging locations. The substrate handling structure comprises one or more fine stages, each of which is configured to support a substrate, and at least one coarse stage that is designed to support a fine stage in a manner such that the coarse and fine stages can be moved together relative to an imaging location, or the fine stage can move relative to the coarse stage. In one embodiment of this aspect of the invention, coarse stages are provided at each of the pair of imaging locations, and a track is configured to transfer a fine stage from a coarse stage at one imaging location to a coarse stage at the other imaging location. In another embodiment of this aspect of the invention, a single coarse stage is located at the pair of imaging locations, and a pair of fine stages is associated with the coarse stage in a manner than enables substrates on both fine stages to be simultaneously imaged at the pair of imaging locations.

In another of its basic aspects, the present invention provides a new and useful metrology structure, for a system in which a metrology device is located under a substrate and under the imaging optics at an imaging location. The metrology structure of the present invention is characterized in that a support member is supported at points on opposite sides of the imaging location, in a manner that enables the position of the substrate to be measured relative to the imaging optics at the imaging location. In one embodiment of that concept, the support member is connected to imaging optics (e.g. the lens barrel of the imaging optics). In another embodiment of that concept, the substrate handling structure comprises a system frame with a portion located below the imaging location and a support member which has a pair of legs on opposite sides of the imaging location, the pair of legs engaging respective portions of the system frame below the imaging location. In addition, with the metrology concept of the present invention, the substrate handling structure is configured to allow a stage exchange procedure (of the type described in this application) at an imaging location, and the support member is configured and supported in a manner that avoids interference with a stage exchange procedure at the imaging location (whereby an immersion liquid is maintained under the projection lens at an imaging location as imaging is switched from the substrate on one stage to the substrate on the other stage without an auxiliary device being temporarily located at the imaging location as part of the exchange process).

Each of the foregoing aspects of the invention provides a new and useful substrate handling concept for use with an imaging optical system that simultaneously images a single reticle to a pair of imaging locations. Moreover, those substrate handling concepts can be used together to provide substrate handling features designed to manage imaging and throughput for substrates whose sizes approach 450 mm and greater.

These and other features of the present invention will be apparent from the following detailed description and the accompanying drawings.

### BRIEF DESCRIPTION OF THE DRAWINGS

FIGS. 1, 1a, schematically illustrate one version of an imaging optical system (referred to as the “Sumo lens”) designed e.g. for a lithographic optical imaging system that images a pair of substrates from a single reticle, and with which a substrate handling structure according to the principles of the present invention is useful;

FIG. 2 schematically illustrates another version of an imaging optical system (referred to as the “Y Wing lens”) e.g. for a lithographic optical imaging system designed to image a pair of substrates from a single reticle, and with which a substrate handling structure according to the principles of the present invention is also useful;

FIGS. 3a-3f schematically illustrate the operating principles of one form of substrate handling structure, according to the principles of the present invention;

FIG. 4 schematically illustrates the operating principles of a form of substrate handling structure, according to the principles of the present invention, that is particularly useful with an imaging optical system of the Y-Wing type;

FIGS. 5a-5c schematically illustrate substrate handling structure that can be used in the practice of the present invention, and also showing one configuration for a metrology device that can be used with an imaging optical system of either the Sumo or Y Wing type (FIGS. 5a and 5b being taken from an orientation looking down at the substrate handling structure through the imaging optics at an imaging location, and FIG. 5c being an end view of FIG. 5a, taken from the direction A-A);

FIGS. 6a and 6b schematically illustrate an alternative structure that is part of a substrate handling structure according to the principles of the present invention, and showing another configuration for a metrology device that can be used with an imaging optical system, according to the principles of the present invention (FIG. 6b being a view of a portion of FIG. 6a taken from the direction B-B); and

FIG. 7 schematically illustrates substrate handling structure of the type described in FIGS. 5a-5c, and particularly showing how that structure can be used in imaging a pair of substrates by an optical imaging system such as the Y Wing lens of FIG. 2.

### DETAILED DESCRIPTION

As described above, the present invention provides new and useful substrate handling structure that is particularly useful with lithographic optical imaging systems, such as the types of lithographic imaging optical systems shown in U.S. application Ser. No. 12/547,086, filed Aug. 25, 2009, which has been incorporated by reference herein.

More specifically, the present invention provides an improved substrate handling structure for an imaging optical system, which is particularly useful with a lithographic imaging optical system that images a single reticle to a pair of imaging locations. The principles of the present invention are particularly useful with an imaging optical system known as the Sumo lens, and with an imaging optical system known as the Y Wing, both of which are disclosed in U.S. application Ser. No. 12/547,086 (attorney reference 6162.121US), which has been incorporated by reference herein.

### Sumo Lens Concept

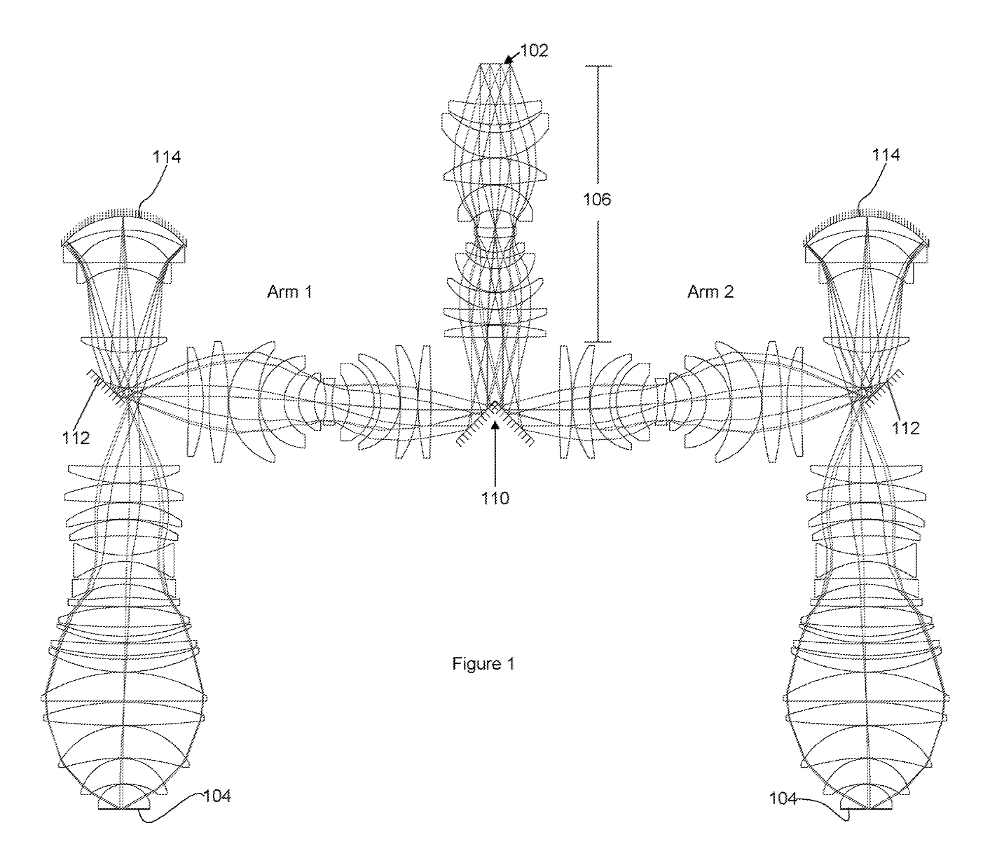

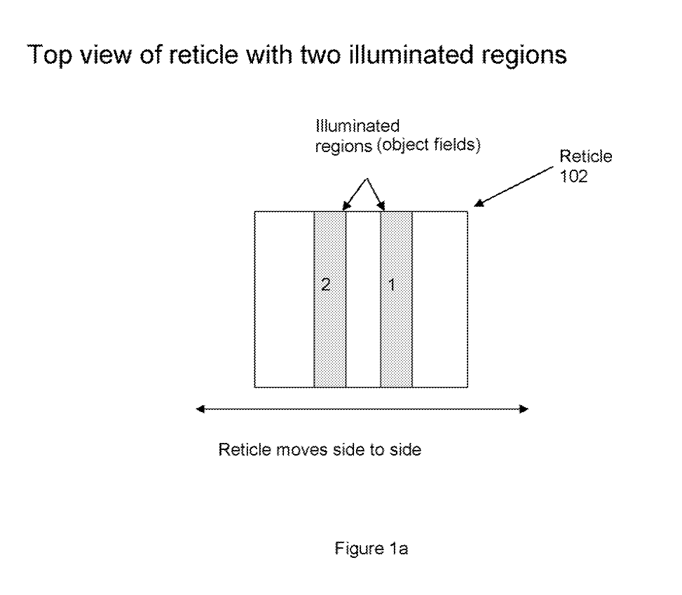

FIGS. 1 and 1a, and the description below, describe the basic structure and principles of the Sumo lens that is shown and described in application Ser. No. 12/547,086 that has been incorporated by reference herein, and with which the principles of the present invention are particularly useful. In the Sumo lens, a single reticle 102 is simultaneously imaged to a pair of image planes 104, which are the imaging locations of the imaging optical system. The reticle 102 can move in the manner illustrated in FIG. 1a, and the reticle is illuminated by a pair of “slits” (narrow, rectangular illuminated regions) 1 and 2, which are imaged to respective imaging locations 104 (associated with slits 1 and 2, respectively) in the manner illustrated in FIG. 1. The slits 1 and 2 comprise different object fields of the reticle that are imaged to the pair of imaging locations by the imaging optical system. It is important to note that the position of the illumination slits is fixed relative to the imaging optics of the imaging optical system, while the reticle scans back and forth so that the entire reticle pattern passes through both of the slits. The Sumo lens comprises a central portion 106, with a series of refracting optics that transmit light from the reticle 102 to a V-fold mirror 110 that separates the light from Region 1 of FIG. 1a to one arm and light from region 2 of FIG. 1a to the other arm. The Sumo lens includes a pair of arms, labeled Arm 1 and Arm 2 in FIG. 1. Each arm comprises catadioptric optics, including (a) a plane mirror 112, a concave mirror 114, a series of refracting optics between the V-fold mirror 110 and the plane mirror 112, and a series of refracting optics between the concave mirror 114 and the imaging location 104 for that arm.

### Y Wing Lens Concept

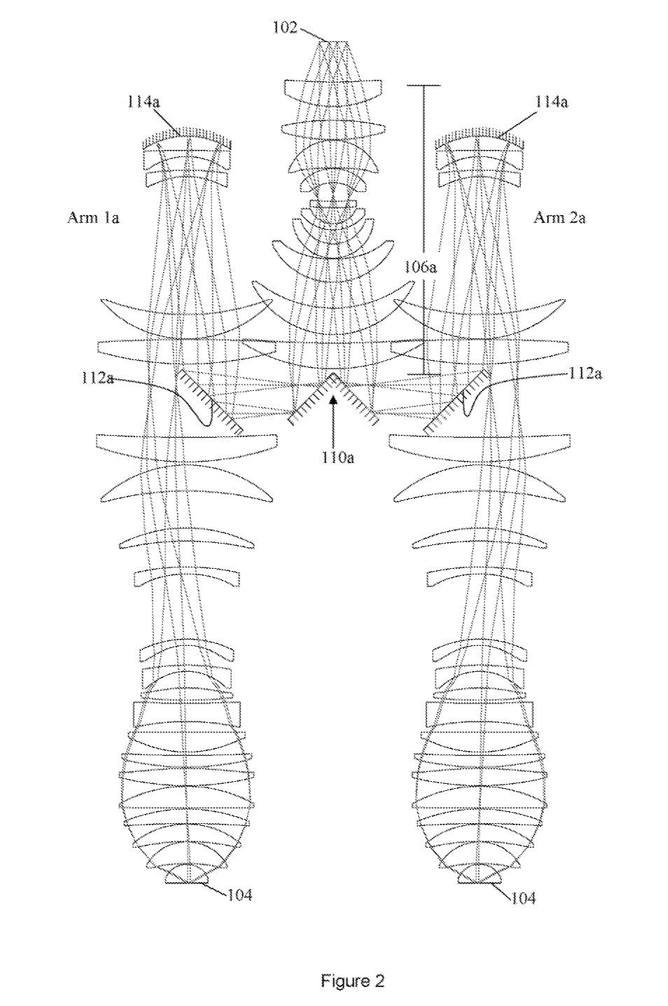

FIG. 2, and the description below, shows the basic structure and principles of the Y Wing lens, with which the principles of the present invention are also useful. The Y Wing lens is more fully described in application Ser. No. 12/547,086 that has been incorporated by reference herein.

In the Y-Wing lens, the reticle 102 would be similar to the reticle of the Sumo lens of FIG. 1. Furthermore, the reticle 102 moves and is illuminated in the manner illustrated in FIG. 1a. Also, the Y Wing imaging optical system has a central portion 106a comprising a series of refracting optics that directs light from the reticle 102 to a V-fold mirror 110a. The Y Wing lens has a pair of arms (Arm 1a and Arm 2a) that are different from the arms of the Sumo lens of FIG. 1, primarily in the transmission of light from the V-fold mirror 110a to the plane mirror 112a of each arm. In the Y Wing lens, there is “direct” transmission between the V-fold mirror 110a and the plane mirror 112a of each arm (meaning that there are no refractive optics along the optical axis between the V-fold mirror 110a and the plane mirror 112a of each arm). Each arm 1a, 2a comprises catadioptric optics, including (a) a plane mirror 112a, a concave mirror 114a, and a series of refracting optics between the concave mirror 114a and the imaging location 104 for that arm. In the Y Wing lens, the pair of imaging locations 104 are relatively closely spaced (e.g. by about 600 mm) and one version of substrate handling structure of the present invention takes advantage of that spacing, as described further below.

In each of the Sumo and Y Wing lenses, the reticle 102 can move in the manner illustrated in FIG. 1a, and the reticle has a pair of slits 1 and 2, which are imaged to respective imaging locations 104 (associated with slits 1 and 2, respectively) in the manner illustrated in FIGS. 1 and 2. In this application, reference to an “imaging location” means a location where an image of a reticle (the “object(s)” or “object field(s)”) is produced at an image plane (the “image field(s)”) on a substrate that is used in the creation of a semiconductor wafer (e.g. by the lithographic imaging optical system principles described in application Ser. No. 12/547,086, which has been incorporated by reference herein). The substrate typically has a photoresist that is imaged and then the image is “developed” to produce the pattern(s) for the wafer. Thus, in this application, reference to an “imaging location” is intended to mean the type of imaging location where a substrate would be imaged (e.g. by a lithographic imaging optical system) in the formation of the patterns that are used to produce a semiconductor wafer. In addition, the concept of “imaging” a substrate may also be referred to in this art as “exposing” or “printing” the substrate with the image of the object field of the reticle. Still further, reference to “imaging a reticle” is intended to encompass transmitting an image of the entire reticle, or of portions of the reticle (e.g. the two different portions of the reticle of FIG. 1a). Moreover, reference to “simultaneously” imaging a reticle to the pair of imaging locations, is intended to allow for periods that one or a pair of substrates being imaged may be in undergoing a “substrate exchange” at the imaging location, as described further below. In addition, reference to “catadioptric imaging optics” means imaging optics that include at least one curved reflective surface (in the disclosed embodiments that curved reflective surface comprises a concave mirror).

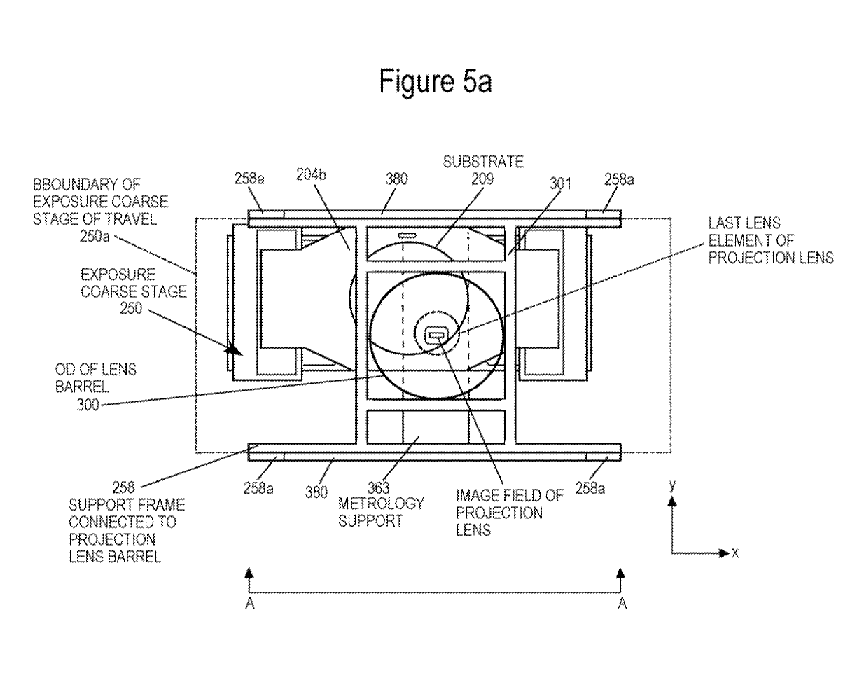

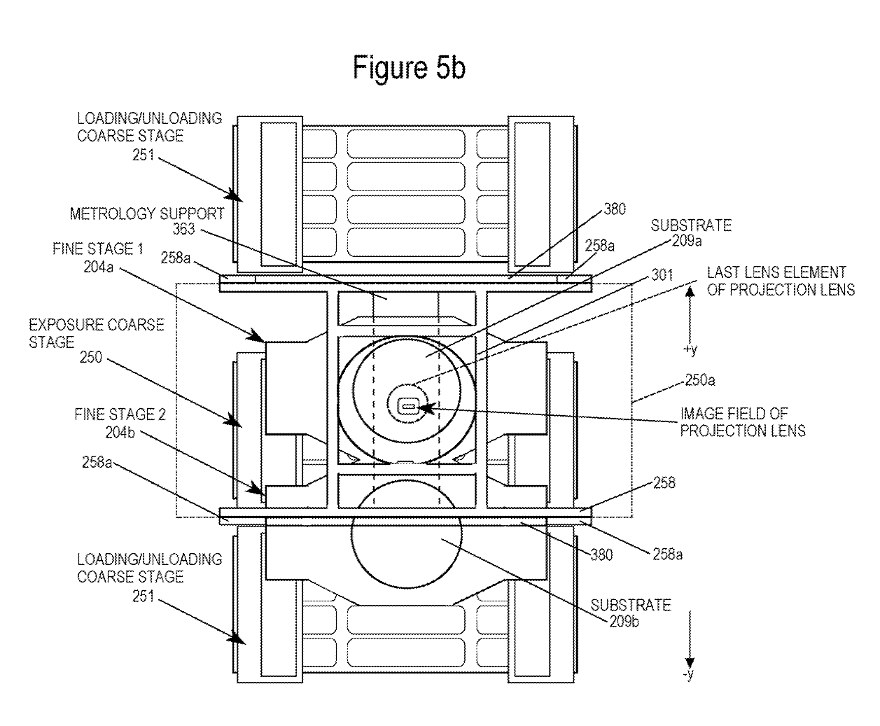

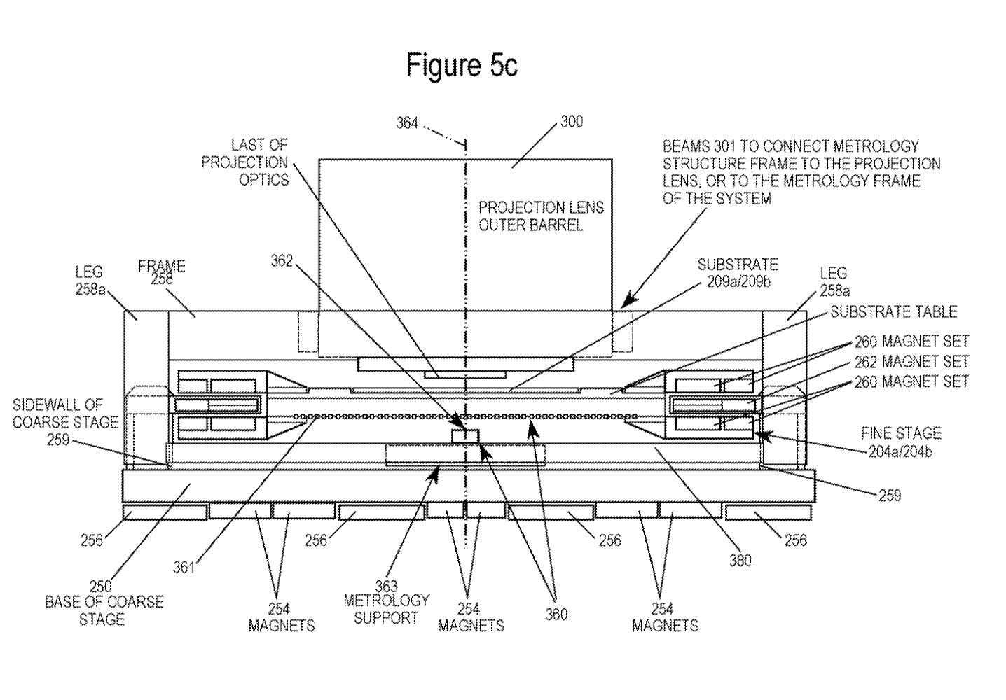

In both the Sumo lens and the Y Wing lens, the catadioptric imaging optics of the arms of the lens would generally be housed with what is known in the art as a “barrel”, which is a generally cylindrical tube within which the imaging optics of the lens are contained. FIG. 5c schematically illustrates the barrel 300 for the imaging optics that can be the imaging optics of one of the arms of the Sumo or the Y Wing lens.

Substrate Handling in Accordance with the Principles of the Present Invention.

Initially, it is believed useful to provide an overview of the concepts of “coarse” and “fine” stages, and also to the concept of “metrology” in connection with substrate handling, since those concepts are important in different aspects of the substrate handling structure of the present invention. A “fine stage” is generally configured to support a substrate that is imaged in accordance with the principles of the present invention (essentially the fine stage includes a “substrate table” with a top surface configured to support a substrate, so reference to a “fine stage” is intended to include the substrate table that supports the substrate). A “coarse stage” is a stage that is associated with a fine stage in a manner that enables the fine stage to move with the coarse stage relative to an imaging location, and that also enables the fine stage to move relative to the coarse stage (and relative to an imaging location). Typically the coarse stage is used to generate large-scale motions in at least one direction with moderate accuracy. The fine stage moves with a smaller stroke relative to the coarse stage to provide precise positioning of the substrate. A coarse stage can be moved relative to an imaging location by a planar (or linear) electromagnetically powered motor, as will be clear to those in the art. In accordance with the principles of the present invention, a fine stage can be supported on a coarse stage in a manner that the fine stage is supported above a coarse stage, and in spaced relation to a coarse stage, and the fine stage can be moved relative to the coarse stage by one or more electromagnetic or other actuators. As seen from FIG. 5a or 5b, projection of the object fields of the reticle to the substrate is via image fields labeled “image field of projection lens,” which are much smaller than the substrates. Thus, imaging of a substrate is accomplished by moving the substrate in predetermined patterns relative to the image fields of the projection lens, and this is accomplished by joint movement of the coarse and fine stages relative to the projection lens. Movement of a fine stage relative to the imaging optics at an imaging location, to control the position and orientation of a substrate on the fine stage, may be controlled in accordance with information provided by a “metrology” device that provides a measurement of the position of a substrate relative to an imaging location (and particularly to the imaging optics at the imaging location).

In accordance with one of the new and useful aspects of the present invention, a substrate handling device provides new and useful structures for moving coarse and fine stages in relation to an imaging optical system that simultaneously images a single reticle to a pair of imaging locations (e.g. the Sumo lens and/or the Y Wing lens). In accordance with another aspect of the present invention, a new and useful metrology device is designed to be located under a substrate and under the imaging optics at an imaging location of the imaging optical system, and provides a measurement of the position of a substrate relative to an imaging location for fine positioning of a fine stage relative to an imaging location. The metrology device of the present invention further develops a concept shown and described in U.S. application Ser. No. 12/561,533, which is incorporated by reference herein.

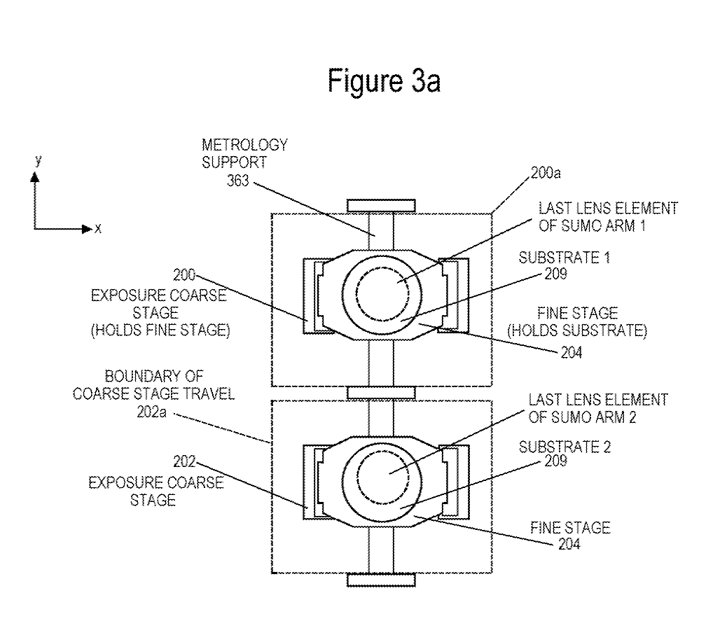

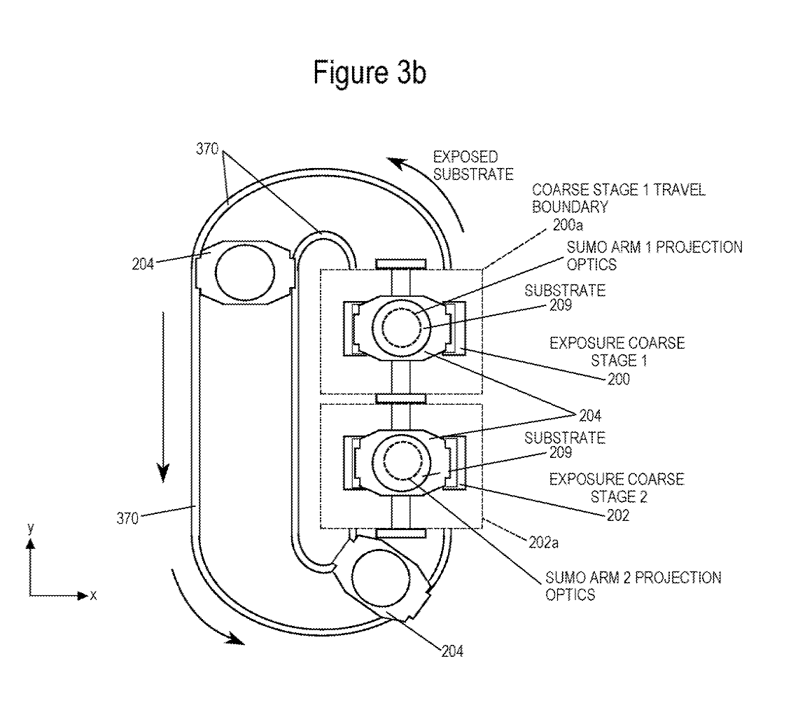

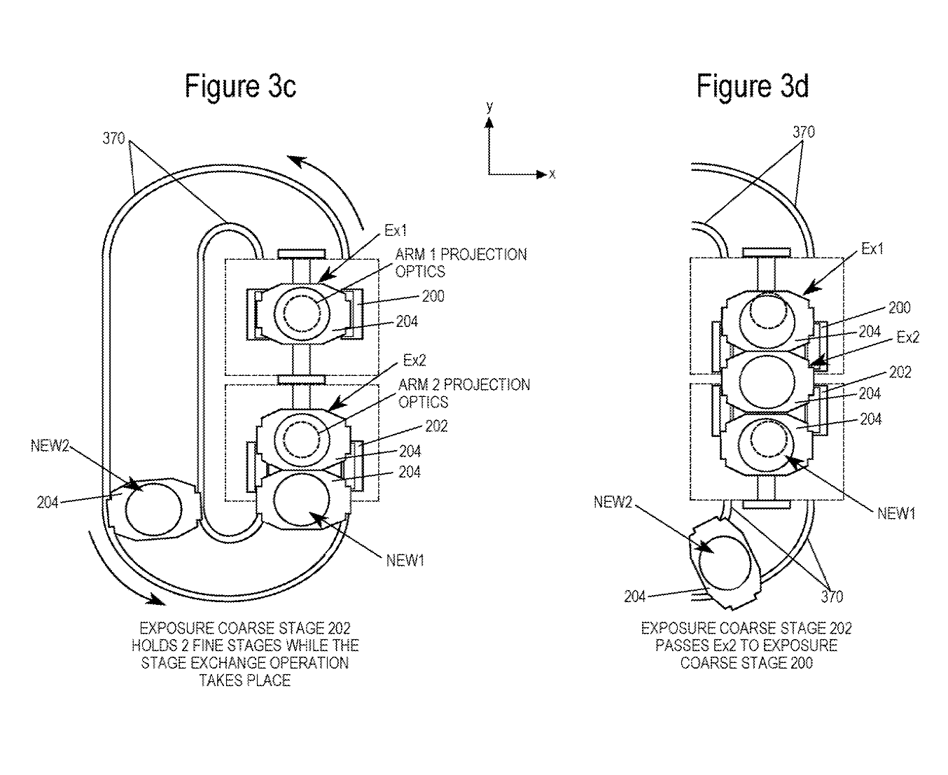

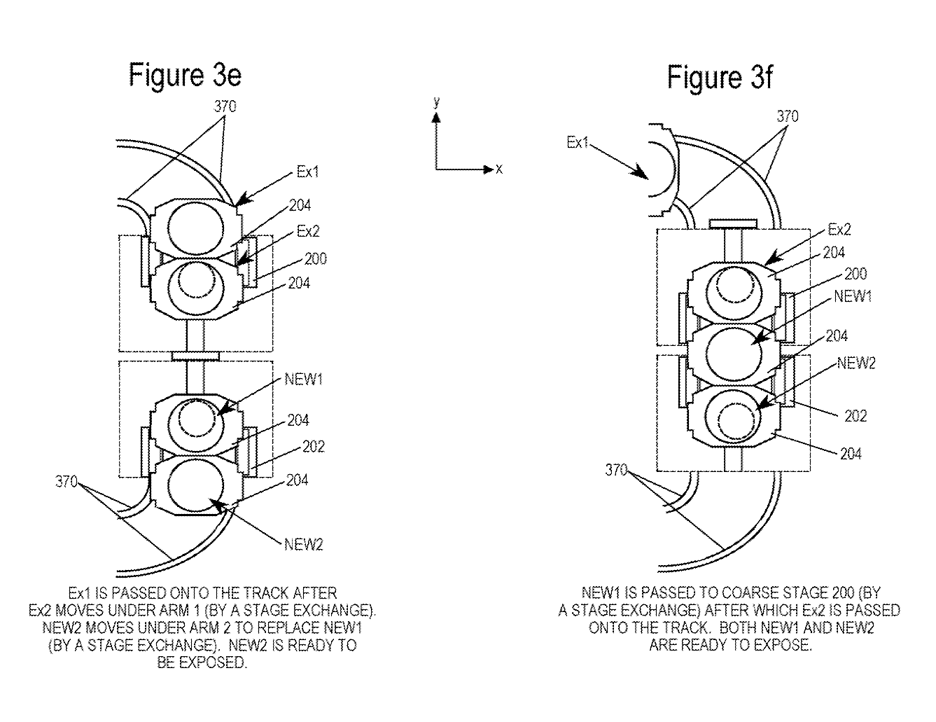

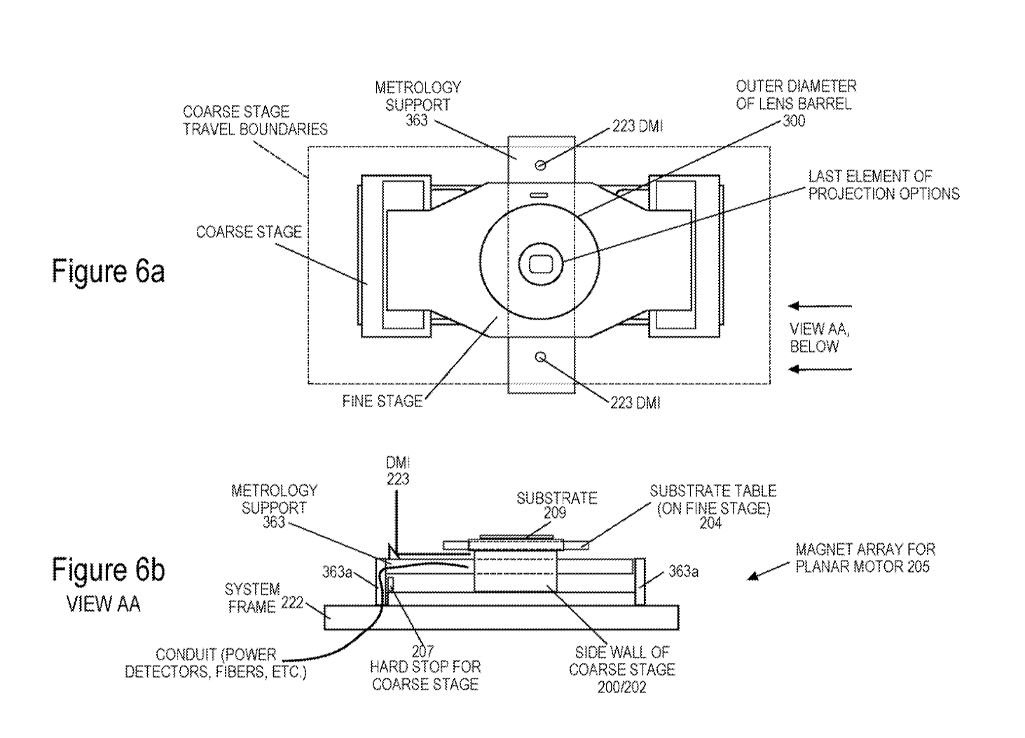

FIGS. 3a-3f and 6a, 6b schematically illustrate one way of providing coarse/fine stage movement and metrology, in accordance with the principles of the present invention. FIGS. 3a-3f show the overall movement patterns of the coarse and fine stages. FIGS. 6a, 6b show details of the coarse and fine stages, and also one version of the metrology support structure of the present invention. Specifically, a pair of “exposure” coarse stages 200, 202 are provided, and each coarse stage is associated with a respective one of the imaging locations (e.g. that is imaged by one of the arms of the Sumo lens). Each coarse stage (200, 202) is moved relative to its respective imaging location, e.g. by planar or linear motors. The range of motion of the coarse stage is limited relative to an imaging location, e.g. by physical or “hard” stops (one of which is shown at 207 in FIG. 6a). The boundaries of the range of motion of the coarse stages 200, 202 are shown at 200a, 202a in FIGS. 3a and 3b.

As will be appreciated from FIGS. 3c-3f, up to a pair of fine stages 204 can be associated with each of the coarse stages 200, 202. Each fine stage 204 has a “substrate table” (FIG. 6b) with a top surface configured to support a substrate that is imaged at an imaging location. Each fine stage 204 is held by a respective coarse stage 200/202 and can move with the coarse stage (over the limited range of movement of the coarse stage relative to an imaging location) during imaging of the substrate at the imaging location. Moreover, each fine stage 204 can be moved relative to a coarse stage (e.g. by electromagnetic actuators), to provide fine adjustment of the substrate relative to the imaging location.

Also, in the substrate handling structure of FIGS. 3a-3f, in accordance with an important aspect of the present invention, a track 370 is provided, for transferring a fine stage (carrying a substrate) from one coarse stage at one imaging location to a coarse stage at another imaging location. The manner by which the track 370 handles a fine stage, in accordance with the principles of the present invention, is described further below.

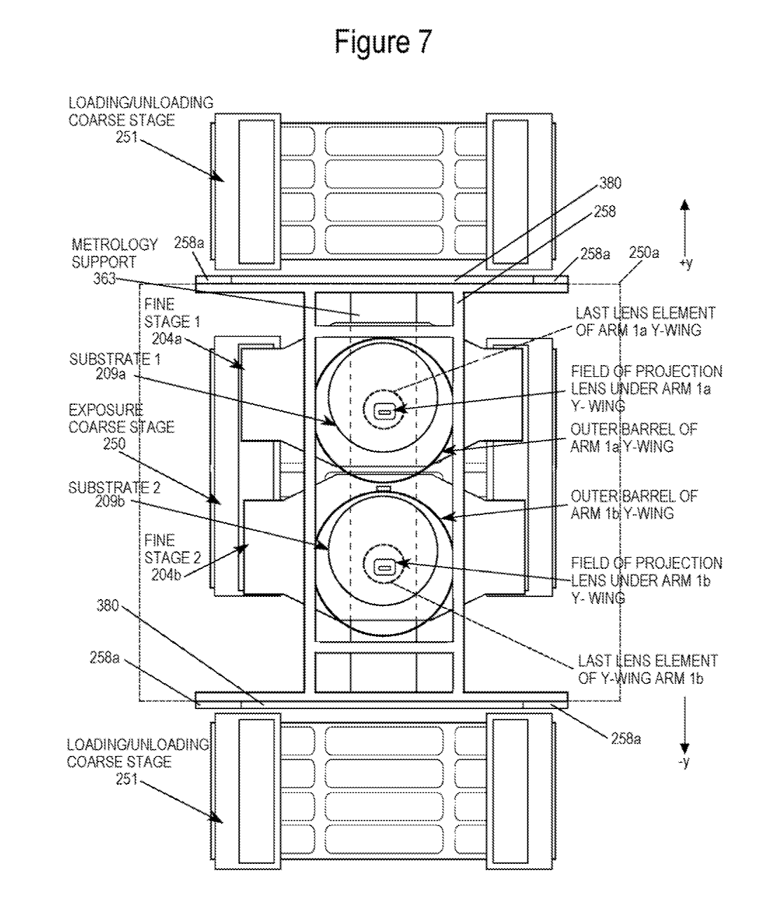

FIGS. 5a-5c, and 7 show another way of providing coarse/fine stage support for a substrate, in a manner that enables substrate handling in accordance with the principles of the present invention. For example, because of the relatively small spacing between the imaging locations of the Y Wing lens, a single coarse stage 250 (which forms an “exposure coarse stage”) is located beneath both imaging locations of the Y Wing lens of FIG. 2. The exposure coarse stage 250 can move over a limited range, in x and y directions during imaging of a pair of substrates 209a, 209b at the imaging locations, and the boundaries of movement of the exposure coarse stage are shown at 250a in FIG. 5b. The system also includes (i) a pair of “loading/unloading coarse stages” 251 on opposite sides of the exposure coarse stage. One of the loading/unloading coarse stages 251 receives fine stages with unexposed substrates and transfers the unexposed substrates to the exposure coarse stage 250. The other of the loading/unloading coarse stages 251 receives fine stages with exposed substrates from the exposure coarse stages, and enables those substrates to be transferred to an unloading location. FIG. 7 schematically shows a single coarse stage 250 with a pair of fine stages supported under the projection lens of an imaging optical system such as the Y Wing lens of FIG. 2.

The exposure coarse stage 250 is moveable e.g. by planar or linear motors that may be electromagnetically driven, e.g. a planar motor would be driven by arrays of magnets 254, 256 attached to the bottom surface of the coarse stage 250 that interact with e.g., coils on a counter mass located below the exposure coarse stage 250, as is known to those skilled in the art. A pair of fine stages 204a, 204b are supported above and spaced away from the exposure coarse stage 250. The fine stages have respective substrate tables that are configured to support substrates 209a, 209b.

A support structure, comprising a frame 258, a pair of legs 258a fixed to the frame 258, a set of magnets 260 carried by the fine stage and a set of coils 262 carried by a sidewalls 259 connected with the exposure coarse stage 250 enable the fine stage(s) 204a, 204b, and their respective substrate tables, to move with the exposure coarse stage 250, or relative to the exposure coarse stage 250. The frame 258 is connected with the machine frame (not shown) or to the projection lens (e.g. to the lens barrel 300 for the imaging optics at an imaging location). By “connected with”, applicants mean that the frame is either directly connected or connected through one or more intermediate members. The support structure supports one of the components of the metrology structure, as described further below. Magnet set 260, and coils 262 form the mover assembly that allows relative movement of the fine and coarse stages. The sidewall 259, shown in FIG. 5c, supports the coils 262. The details of the types of actuators that are used between the coarse and fine stages are known to those in the art, and are not part of this invention. Applicants have illustrated an embodiment that has magnets on the fine stage and coils on the coarse stage, but that is just one example, as will be recognized by those in the art.

In accordance with the concept of U.S. application Ser. No. 12/561,533, which has been incorporated by reference herein, a metrology device is located under a substrate on a fine stage (preferably between the substrate table on the fine stage and the coarse stage), and under the imaging optics at an imaging location, as also described further below. The present invention further develops the concepts of that published application, by providing a metrology support 363 supported at points on opposite sides of the imaging location. In one embodiment of that concept, described further in connection with FIG. 5c the imaging optical system includes a lens barrel 300 for at least part of the imaging optics at an imaging location, and the metrology support 363 is connected with the lens barrel of the imaging optics, by means of a support member 380 that is connected with the lens barrel 300 by legs 258a, frame 258 and beams 301. In another embodiment of that concept, described further in connection with FIG. 6b, the substrate handling structure comprises a system frame 222 with a portion located below the imaging location, and the metrology support 363 has a pair of legs 363a on opposite sides of the imaging location, the pair of legs engaging respective portions of the system frame 222 below the imaging location. With the metrology concept of the present invention, the substrate handling structure is configured to allow a stage exchange procedure of the type described in this application (where an immersion liquid is maintained under the projection lens at an imaging location as imaging is switched from the substrate on one stage to the substrate on the other stage without an auxiliary device being temporarily located at the imaging location as part of the exchange process), and the metrology support is configured and supported in a manner that avoids interference with a stage exchange procedure at the imaging location. More specifically, the metrology concept of the present invention enables a stage exchange procedure at an imaging location where a fine stage carrying an exposed substrate is released from a coarse stage in one direction (e.g. the +y direction in the figures) and a fine stage with a substrate to be exposed at the imaging location is captured by the coarse stage from the other direction (e.g. from the −y direction in the figures). This involves a single coarse stage temporarily carrying two fine stages as the stage exchange procedure occurs, a process that does not require extremely accurate motion as no printing is happening during the stage exchange procedure (as shown in FIGS. 3c, 3e and 3f, for example).

In the structure of FIGS. 5a-5c, and 7, a metrology device is connected by the metrology support 363 to the imaging optics of the imaging optical system. The metrology device is located under the substrate tables on the fine stages 204a, 204b (between the substrate tables and coarse stages), and “under” the imaging optics of each of the “arms” of the imaging optical system (i.e. directly beneath and in line with the optic axis 364 of each arm of the imaging optics at each imaging location). Specifically, the metrology device of FIGS. 5a-5c and 7 comprises a pair of metrology components 360 (e.g. an encoder scale 361 on the underside of the fine stage and a read head 362 carried by the metrology support 363 that is connected with the barrel 300 of the imaging optics, via the beam 301 frame part 258, legs 258a and support member 380), so that the metrology read head 362 is always in fixed relation to the projection optics at the imaging locations. Also, in accordance with the principles of the present invention, the metrology support 363 is supported at a pair of support points of the support member 380 that are located on opposite sides of the imaging location. Thus, the support points for metrology support 363 are on the opposite sides of the projection optics at an imaging location e.g. each of the imaging locations shown in FIGS. 5a, 5b and 7). In addition, the manner in which the support structure for the metrology support is configured is designed to enable substrates to be exchanged at an imaging location by the stage exchange process described below (whereby an immersion liquid is maintained in the gap under the projection lens at an imaging location as imaging is switched directly from the substrate on one stage to the substrate on the other stage without an auxiliary device being temporarily located at the imaging location as part of the exchange process). The configuration of the substrate handling structure that supports the metrology device is configured to enable a stage exchange procedure at an imaging location where a fine stage carrying an exposed substrate is released from a coarse stage in one direction (e.g. the +y direction in FIGS. 5b, 7) and a fine stage with a substrate to be exposed at the imaging location is captured by the coarse stage from the other direction (e.g. from the −y direction in FIGS. 5b, 7).

The metrology components 360 can comprise e.g. one or more encoder scales 361 on the bottom of the fine stages that are each read by an associated metrology component 362 which can comprise e.g. one or more read heads on the metrology support 363. Both of the metrology components 361, 362 are located under the substrates and respective imaging optics at the imaging locations, e.g. as seen in FIG. 5c, both of the metrology components 361, 362 are optical metrology components that are located under the substrate and imaging optics, and in line with the optic axis 364 which extends through the imaging optics at each imaging location. With such structure, a metrology component (read head) 362 on the metrology support 363 can read one or more positions of an associated metrology component (encoder scale 361) under the substrate fine stage to provide information about the position and orientation of the fine stage (and substrate) relative to the imaging optics (either as a substrate is being positioned prior to being exposed by the imaging optics, or during exposure of the substrate by the imaging optics). The information provided by the metrology components 361, 362, can be used to measure the position of the substrates 209a/209b relative to the imaging optics at an imaging location.

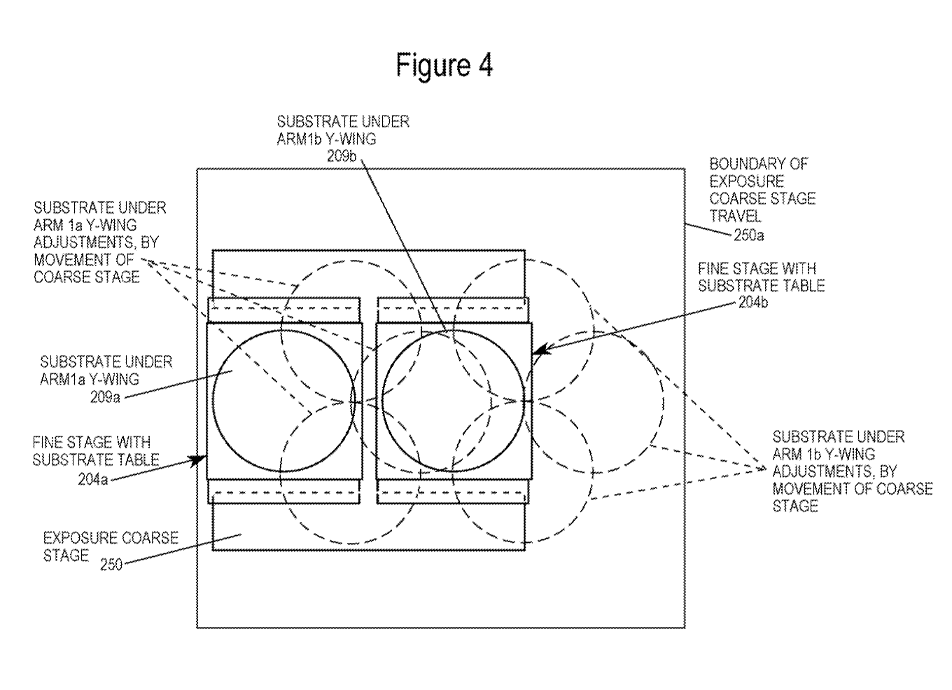

In an imaging optical system such as the Y-Wing lens, FIG. 4 schematically shows that principles by which coarse and fine stage adjustment can be provided. In the Y Wing lens, a pair of fine stages are supported by (and in spaced relation above) a single exposure coarse stage 250. Movement of the coarse stage provides gross movement of the pair of fine stages (and their substrates) relative to the imaging locations of the Y Wing lens. Thus, in FIG. 4, the circles shown in full and dashed lines indicate the range of where the substrates can be positioned by gross movement of the exposure coarse stage. The adjustment range of each of the fine stages relative to the coarse stage and relative to the imaging optics associated with each of the fine stages is much smaller than that of the coarse stage. The range of independent adjustment of the fine stages, in connection with the imaging of the substrates on the fine stages, may be, for example, on the order of a few millimeters or less. However, it will also be appreciated that a fine stage can move considerably more relative to a coarse stage (e.g. in the y direction, as indicated in FIGS. 3a-3f) to allow the stage exchange procedure described herein, whereby pairs of fine stages are transferred to or from the exposure coarse stage 250 by loading/unloading coarse stage(s) 251, or alternatively by the two ends of the circular track 370.

In the metrology system of FIGS. 6a, 6b, there would also be metrology components located beneath the imaging optics at each imaging location, similar to the metrology components 361, 362 described above. The metrology support 363 in FIGS. 6a, 6b is connected to a system frame by means of a pair of legs 363a located at points on opposite sides of the imaging location (in FIG. 6b, the imaging location would essentially extend through the substrate). Thus, in FIGS. 6a and 6b, the metrology support 363 has a pair of legs 363a that connect the metrology support to the system frame (and not to the barrel 300 of the imaging optics). A pair of distance measuring interferometer(s) (DMI(s)) 223 are optically connected with the metrology support 363, and provide information as to the location and orientation of the metrology support relative to the imaging optics. Alternatively, within the scope of this invention, this information may be provided by other types of position and/or orientation measuring sensors besides DMIs. This information, combined with the information provided by the metrology components under the substrate and the imaging optics, is used to measure the position and orientation of a fine stage relative to the imaging optics. If necessary, a conduit could be provided inside the metrology support 363 (and the legs 363a), providing a means for electrical or optical fiber connections to any metrology instrumentation, as shown schematically in FIG. 6b. In the structure of FIGS. 6a, 6b, the bottom of the coarse stage side walls (259 in FIG. 5c) extend below the metrology device. The coarse stage side walls support the fine stage and are far enough apart to allow the required travel of the coarse stage in the x direction to enable the substrate to be exposed without the side walls of the coarse stage touching the metrology structure. In addition, the overall configuration of the metrology structure of FIGS. 6a, 6b, including the metrology support 363 supported by the legs 363a at points on opposite sides of the imaging location, enables substrates to be exchanged at an imaging location by the stage exchange process described below.

Thus, in both the metrology device of FIG. 5c, and the metrology device of FIGS. 6a, 6b, metrology is performed by the metrology components located under the substrate and under the imaging optics at the imaging locations. Moreover, in both concepts, the metrology structure is designed such that substrates can be exchanged at an imaging location by the stage exchange process described below. In each of the metrology concepts, the metrology support 363 is coupled with the system frame (or with the imaging optics, e.g. with the lens barrel 300 of the imaging optics) in a manner that enables a stage exchange procedure at an imaging location where a fine stage carrying an exposed substrate is released from a coarse stage in one direction and a fine stage with a substrate to be exposed at the imaging location is captured by the coarse stage from the other direction.

This concept in metrology is believed to be increasingly important as tighter control of image position becomes more important, and as substrate sizes grow larger. This metrology concept should reduce the uncertainty in substrate positioning during printing and improve the overlay capabilities for an imaging optical system. Current approaches use laser beams incident on the side of the stage that can be incident on a stage mirror located up to 1 wafer diameter or more away from the imaging location, providing for position uncertainty in the form of any stage deformation/expansion. Also, when the stage mirror is close to the print location (when printing the near side of the substrate), the large air path of the DMI beam results in larger position uncertainty due to air temperature fluctuations, as is apparent to those in the art. Another common current approach is to use encoder scales located on the top of the substrate stage, which reduces the air turbulence problem but can cause problems for water contamination from the immersion fluid and, more importantly, aren't measuring at the actual print location but rather up to 1 substrate diameter or more from the actual print location, which can lead to errors. Measuring as close to the print location as possible (i.e. directly below the substrate and the imaging optics at an imaging location) eliminates much of the air turbulence and stage warping/expansion effects from influencing the measured position of the substrate during printing. Also, with the DMI(s) 223 of FIGS. 6a, 6b, since an optical DMI beam can be briefly blocked when fine stage motion requires it, there is a DMI on both ends of the metrology support 363, to provide redundancy, and so that another optical DMI beam can be used to maintain substrate positioning capabilities at all times and for all fine stage positions. Moreover, the structure of FIGS. 5a-5c and 7 (where the metrology support 363 is connected with the barrel 300 of the projection optics), may avoid a need for distance measuring interferometer(s), such as the DMIs 223 shown in FIGS. 6a, 6b.

In the substrate handling structure of FIGS. 3a-3f, 6a and 6b, there is a coarse stage (200, 202) at each of the pair of imaging locations (e.g. of the Sumo lens). A pair of fine stages 204 can be associated with each coarse stage, and a track 370 (FIGS. 3b-3f) is provided that extends from the coarse stage at one imaging location to the coarse stage at the other imaging location. The track 370 has an approximately oval (racetrack like) configuration, and enables a fine stage to be efficiently moved from one imaging location to the other imaging location, thereby to enable imaging of a substrate on the fine stage at both of the imaging locations.

In FIGS. 3a, 3b, two substrate fine stages 204 that are located on respective coarse stages 200, 202 can both be positioned under the imaging locations of the Sumo lens with a high level of position control. The track 370 enables shuttling the substrate fine stages 204 from one imaging location to another (e.g. in the Sumo lens, from a coarse stage at one imaging location to the coarse stage at the other imaging location). Moreover, when a fine stage 204 has separated from a coarse stage (200, 202) and is moving along the track 370, magnetic levitation and motive means can also be used to move the fine stage along the track 370.

Thus, in FIGS. 3a, 3b, when used with an imaging system such as the Sumo lens, substrate 1 (top) and substrate 2 (bottom) should finish exposing at approximately the same time, at which point they must be replaced by two new substrates while the water body under each arm of the Sumo lens remains in place. The substrate handling system of FIGS. 3a-3f requires a minimum of 4 fine stages 204, and 2 to 4 coarse stages (preferably 2), depending on the motion path chosen. The embodiment of FIGS. 3a-3f utilizes 2 coarse stages 200, 202, and 4 fine stages 204. The first motion path disclosed is to have the track 370 configured to receive the fine stage that is unloaded (separated) from the coarse stage at +y of Sumo arm 1 (top) and send it around one side of the Sumo system to the bottom, where the exposed substrate is unloaded and replaced with a new substrate. The motion tolerances for this path are much less stringent than those for movement of a fine stage during exposure.

One important aspect of the oval track design of FIGS. 3a-3f is that each exposure coarse stage 200, 202 is capable of carrying two fine stages 204 (with substrates) simultaneously, at low speeds and for short time periods. This will allow each “stage exchange” operation described below (effectively exchanging a substrate at an imaging location directly for another substrate at the imaging location while maintaining the water body of the immersion projection lens substantially intact) to occur without using an auxiliary stage. In FIG. 3c, two substrates have just finished exposing (Ex1 and Ex2) on the first two fine stages, and two new, unexposed substrates (New1, New2) have been loaded on the other two fine stages. New1 and Ex2 are both carried by exposure coarse stage (CS) 2 for the first stage exchange (described below).

The procedure, by which a fine stage displaces another fine stage at an imaging location and begins exposure of the substrate on that fine stage at the first imaging location, is referred to as “stage exchange.” This procedure involves moving the two fine stages close together so they form a substantially continuous surface and moving them together in order to maintain an immersion liquid in the gap under the projection lens (at an imaging location) as imaging is switched directly from the substrate on one fine stage to the substrate on the other fine stage. An example of the stage exchange procedure is shown and described in U.S. Pat. No. 7,327,435, which is owned by the assignee of the present application, and is incorporated herein by reference. Thus, reference to a “stage exchange” in this application is intended to mean the type of procedure illustrated and described in U.S. Pat. No. 7,327,435 by which the fine substrate stages move together and immersion liquid is maintained in the gap under the projection lens (at an imaging location) as imaging switches from a substrate on one fine stage to a substrate on another fine stage at the imaging location. It should also be noted that in the stage exchange procedure to which the present invention relates, an immersion liquid is maintained in the gap under the projection lens at an imaging location as imaging is switched directly from the substrate on one stage to the substrate on the other stage without an auxiliary device being temporarily located at the imaging location as part of the exchange process). Of course in a non-immersion lithography machine the stages can be spaced somewhat further apart during the stage exchange motion, as will be appreciated by those in the art. Moreover, it should be noted that that because there are two imaging locations, each substrate must stage exchange in and out from under the leg that it doesn't print under. For example, in FIG. 3c, New1 only exposes under Arm 1, but it must ‘stage exchange’ under Arm2 on it's way to Arm1, even though it is never exposed under Arm2.

In FIG. 3d, a fine stage holding substrate Ex2 is being transferred from coarse stage 202 to coarse stage 200. In FIG. 3e, a fine stage holding substrate Ex1 is passed onto the track after the substrate Ex2 undergoes a “stage exchange” under Arm 1 to replace it. A fine stage holding substrate New2 undergoes a “stage exchange” under Arm 2 to replace the substrate New1, at which point New2 is in position to start exposing. In FIG. 3f a fine stage holding substrate New1 is passed from coarse stage 202 to coarse stage 200 and undergoes a “stage exchange” under Arm 1, replacing substrate Ex2, after which the fine stage holding substrate Ex2 is passed onto the track. Finally, both new substrates are ready to begin exposure and substrates from Ex1 and Ex2 are ready to be unloaded from the system. As will be understood by those in the art, the precise timing and sequence of these operations may be modified within the scope of this invention. For example, the substrate New2 may begin exposure earlier than the substrate New1. Furthermore, it is possible for each substrate to be partially exposed under Arm 1 and have the remainder of the substrate exposed under Arm 2. In this case, the system only requires 3 fine stages.

Similarly, the “stage exchange” principles, described above, can be used with a system as shown in FIGS. 5a-5c and 7, where pairs of fine stages may be loaded on, or unloaded from, an exposure coarse stage, from either (or both) of a pair of loading/unloading coarse stages 251 located upstream and downstream of the exposure coarse stage, as described further below, or the system can utilize a track as described in FIGS. 3a-3f.

The footprint of the type of substrate handling system of the present invention is relatively small. For example, in the substrate handling system shown in FIGS. 3a-3f the fine stages move back in the −Y direction via the track 370 that runs along the side of the system, and not using the same motive system that drives the coarse stages within the exposure area. Preferably, the fine stages do not require permanently attached cables or hoses that would prohibit a circulating motion path as described above. Alternative configurations where the fine stages move in a back-and-forth motion, instead of circulating around a closed circuit, would permit cables and/or hoses to the fine stages. Substrate loading and unloading can happen anywhere after the fine stage leaves the coarse stage 200 but before it enters the coarse stage 202. Likewise, alignment measurements of the substrate (e.g. by the metrology system described herein, or mapping of the wafer surface by an autofocus system, etc) can take place anytime after the new substrate has been loaded but before exposure begins.

In regard to the use of planar or linear motors, e.g. in the system shown in FIGS. 5a-5c, 7, it should be noted that the two exposure coarse stages do not necessarily need to be planar motors, since they don't need to cross each other's paths. They could simply each be a pair of stacked linear motor stages, one for x direction and one for y direction, as will be recognized by those in the art. The linear motor design would still need to incorporate space for the metrology device such that the position of the substrate can be measured at the exposure location, as discussed herein. In applicants' experience high accuracy linear motors may be simpler to implement than high accuracy planar motors, but it will be recognized by those in the art that the specific configuration of the mover for a coarse stage is not material to the practice of a system according to the principles of the present invention.

The substrate handling structure of 5a-5c and 7, while useful for either of the Sumo lens or Y Wing lens principles, is particularly useful with an imaging optical system such as the Y Wing lens, where the pair of imaging locations are relatively closely spaced (e.g. less than 1 m). The single exposure coarse stage 250 is located at the pair of imaging locations. A pair of fine stages 204a, 204b are associated with the exposure coarse stage 250, and each of those fine stages includes a substrate table configured to support a substrate on the fine stage. The fine stages 204a, 204b are located above the exposure coarse stage, which is driven by a planar motor, linear motors, or another means and can travel only within the boundary 250a as shown. As described above, the metrology device comprises (i) metrology components (e.g. encoder scales 361) located on the bottom of each of the fine stages, and (ii) metrology components (e.g. read heads 362) on the frame 258/363 that is connected with the barrel 300 of the projection optics (e.g. by the support 380, legs 258a, frame 258 and beam 301 referenced in FIG. 5c). Thus, the metrology device(s) is (are) supported mechanically by the same mechanical system that supports the projection lens, and the metrology components are located under the substrates on the fine stages, and under the imaging optics at the imaging locations. Therefore, there may be no need for a DMI or other means (as with the embodiment of FIGS. 3a-3f and 6a, 6b) to measure the relationship between the imaging optics and the metrology device(s) in order to determine substrate position relative to the imaging optics. However, it is recognized that measurement as provided by the DMI(s) may still be useful in the event the mechanical structure is not sufficiently stiff.

When a substrate is done with exposure at an imaging location, the exposure coarse stage 250 picks up fine stages that have new substrates, for example, from the coarse stage 251 on one side of the exposure coarse stage, and from the −y direction, from the coarse stage 251 on the other side of the exposure coarse stage, by the “stage exchange” operation described herein, as shown in FIG. 5b. The frame 258 defines a rectangular space (or opening, as seen in FIG. 5c) that allows fine stages to pass through and join or leave the exposure coarse stage 250. The exposure coarse stage/fine stage combination is restricted from moving in the x-direction during the substrate exchange by the size of the rectangular space, but this does not affect the overall system utility. A “stage exchange” operation takes place as the exposure coarse stage moves in +y, and exposed substrates and fine stage are transferred through an identical rectangular space (opening) in the opposite side of frame 258 to the loading/unloading coarse stage 251 on the other side of the exposure coarse stage.

The use of a track, similar to the track 370 described above in connection with FIGS. 3a-3f, can also be used with the exposure coarse stage-loading/unloading principles shown in FIGS. 5a-5c, 7, and with the implementation of those principles for imaging a pair of substrates on a single exposure coarse stage, by the Y Wing lens. For example, a track similar to the track 370 in FIGS. 3a-3f, can be used in place of loading/unloading coarse stage(s) 251 to transfer an exposed substrate from the exposure coarse stage to an unloading location, and to transfer an unexposed substrate to the exposure coarse stage.

Thus, when the substrate handling structure of FIGS. 5a-5c, 7, is used with the Y Wing lens, a pair of substrates are located on respective fine stages. Those fine stages 204a, 204b are carried above the exposure coarse stage 250 as they are being imaged at the imaging locations. Gross movement of the coarse and fine stages relative to the imaging locations (e.g. in the patterns shown in FIG. 4) is controlled by the magnet arrays 254, 256. Fine adjustment of a fine stage (and its substrate) relative to the exposure coarse stage and to an imaging location, is provided by the actuator(s) comprising the magnet sets 260 and coils 262. The metrology device(s), comprising the metrology components 361, 362 are located between the underside of the fine stages supporting the substrates and the exposure coarse stage. The metrology support 363 is supported mechanically by the same mechanical system that supports the projection lens (e.g. by the support member 380, the legs 258a, frame 258, and beam 301). The metrology support 363 is below the plane of the substrate fine stages, and is supported at points on opposite sides of an imaging location. The substrate position(s) are monitored directly below the imaging location. In a system designed for the Y Wing lens, with the coarse and fine stage movements shown in FIG. 4, this metrology structure would be long enough to extend under both fine stages, providing two sets of metrology components 361, 362 (each associated with a respective one of the fine stages, and each associated with the metrology support 363) for measuring the positions of the two fine stage substrate locations relative to the exposure coarse stage and a respective imaging location. Frame 258 would be connected with the projection lens barrels 300 of both arms of the Y Wing lens, and thus mechanically link the two imaging locations of the Y Wing lens to each other and to the metrology structure 363.

The substrate handling structure of FIGS. 5a-5c is particularly useful with the Y Wing, because of the relatively small spacing of the imaging locations (for example, on the order of 600 mm). However, in the case of the Sumo lens, the workspace of the two coarse stages do not need to intersect, so each exposure arm (and associated coarse stage) can easily have a separate metrology device. For implementations of a system with the Y-Wing lens, there generally cannot be a support structure between the two imaging locations because it might interfere with the coarse stage motion, due to the relatively small separation of the two imaging locations compared to the size of the substrates. However, depending on the specific application of an exposure apparatus, there may be some cases where a central support can be used with a Y-Wing lens. A relatively simple mechanical connection between the projection lens and the mechanical structure is used to establish the offset between the lens and the metrology structure used to measure the position of the substrate. Space in the structure allows fine stages carrying substrates to be exchanged without any mechanical interference, as described above. The substrate position metrology measures directly below the substrate(s) and imaging location(s), as described above. This structure should help to achieve a high throughput system with improved overlay, which is important for larger substrates, smaller features, and double patterning.

Alternatively, two separate exposure coarse stages could be used with the Y-Wing lens, each carrying a single fine stage during exposure, as long as the metrology structure 363 (as in FIG. 7) is long enough to span through both coarse stages for the reasons described above. The motion paths of the two exposure coarse stages would have to be arranged such that they didn't run into each other during exposure.

Although the main purpose of the coarse stage/fine stage arrangement and metrology structures is to accommodate a Y-wing or Sumo type exposure system, many of the principles described here are applicable to a traditional (one reticle and one substrate) lithography system. For example, the metrology support 363 as shown in FIGS. 5a and 5b is drawn for a traditional lithography system, where the 258 frame is essential for allowing measurement of the substrate table position directly under the print location when it is mounted at both ends. In the case of a single substrate system, there is no need for a track system to shuttle the fine stages back and forth. Two fine stages are required to optimize throughput, as shown in FIGS. 5a, 5b.

A system according to the principles of the present invention is designed to provide a high throughput system with a relatively small footprint. Since the substrate handling structures disclosed in this application are likely to be used in an immersion imaging optical projection system, it is important to always have a stage under the projection lens (i.e. the imaging optics at an imaging location) to maintain the water body of the immersion imaging optical system. One advantage of the separable coarse stage/fine stage configuration of the present invention is that the fine stage (and the substrate) position can be determined at or near the region of exposure, by looking at the metrology component (e.g. the encoder scale 361) on the bottom of the fine stage (or substrate table). Another useful feature of the present invention is that the metrology structure is designed to allow a substrate exchange procedure (of the type described in this application) at an imaging location, with the metrology support configured and supported in a manner that avoids interference with a stage exchange procedure at the imaging location

Accordingly, from the foregoing disclosure, those in the art will appreciate that in one of its basic aspects, a substrate handling structure according to the principles of the invention includes substrate moving structure that includes coarse and fine stages for moving a substrate relative to an imaging location, and a metrology device located under a substrate and under the imaging optics at an imaging location, is supported in a manner that enables a stage exchange procedure of the type disclosed in this application. In a preferred embodiment, the metrology device is connected with the support structure for the imaging optics of the imaging optical system (i.e. the lens barrel 300).

Moreover, those in the art will also appreciate that in another of its basic aspects, the substrate handling structure according to the principles of the present invention, provides coarse stages at each of a pair of imaging locations, and a track that is configured to transfer a fine stage from a coarse stage at one imaging location to a coarse stage at the other imaging location (and this handling structure is particularly useful with an imaging optical system such as the Sumo lens). In addition, the substrate handling structure of the present invention is also configured to provide a single coarse stage at a pair of imaging locations, and a pair of fine stages associated with the coarse stage in a manner than enables substrates on both fine stages to be simultaneously imaged at the pair of imaging locations.

These features are designed to provide benefits in providing information as to substrate position as the substrate is being imaged, while reducing the size of the support structure, and these features are believed to be important as imaging of substrates in the 450 mm diameter range is developing.

Thus, the present invention provides substrate handling structure designed to work with an imaging optical system that images a single reticle to a pair of imaging locations, and in a way that provides effective metrology and effective substrate movement between the imaging locations. With the foregoing disclosure in mind, the manner in which the principles of the present invention may be applied to various imaging optical systems will become apparent to those in the art.

1. A substrate handling structure for an imaging optical system of the type that images a reticle to an imaging location, where a metrology device includes a support member located under the imaging optics and under the substrate at the imaging location, and the metrology device is configured to enable the position and/or orientation of a substrate to be measured relative to the imaging optics, characterized in that the support member is supported at points on opposite sides of the imaging location.

2. The substrate handling structure of claim 1, further characterized in that the imaging optical system includes imaging optics at an imaging location, and the support member is connected with the imaging optics.

3. The substrate handling structure of claim 1, further characterized in that the substrate handling structure comprises a system frame with a portion located below the imaging location, and the support member has a pair of legs on opposite sides of the imaging location, the pair of legs engaging respective portions of the system frame below the imaging location.

4. The substrate handling structure of claim 1, further characterized in that the substrate handling structure is configured to allow a stage exchange procedure at an imaging location, and the support member is configured and supported in a manner that avoids interference with a stage exchange procedure at the imaging location.

5. A substrate handling structure for an imaging optical system that images a single reticle to a pair of imaging locations, comprising
a pair of coarse stages, each of which is associated with a respective one of the imaging locations, and at least two fine stages, each fine stage configured to support a substrate, the coarse and fine stages configured such that
a fine stage is supported by a coarse stage at one imaging location,
the fine and coarse stages can be moved together over a limited range of movement of the coarse stage at the one imaging location, and
the fine stage is separable from the coarse stage and moveable along a predetermined path; and
a track that is oriented to engage a fine stage that separates from a coarse stage at the one imaging location and guides the fine stage along the predetermined path to the other coarse stage at the other imaging location.

6. The substrate handling structure of claim 5 wherein a metrology device is associated with at least one imaging location, the metrology device comprising a pair of metrology components located under the imaging optics at each imaging location, to enable the position of a substrate to be measured relative to the imaging optics, and characterized in that the support member is supported at points on opposite sides of the imaging location.

7. The substrate handling structure of claim 6, further characterized in that the imaging optical system includes imaging optics at an imaging location, and the support member is connected with the imaging optics.

8. The substrate support structure of claim 6, further characterized in that the substrate handling structure comprises a system frame with a portion located below the imaging location, and the support member has a pair of legs on opposite sides of the imaging location, the pair of legs engaging respective portions of the system frame below the imaging location.

9. The substrate handling structure of claim 6, further characterized in that the substrate handling structure is configured to allow a stage exchange procedure at an imaging location, and the support member is configured and supported in a manner that avoids interference with a stage exchange procedure at the imaging location.

10. The substrate handling structure of claim 5, wherein the imaging optical system comprises a lithographic imaging optical system.

11. A substrate handling structure for an imaging optical system that images a single reticle to a pair of imaging locations, comprising
a coarse stage associated with the pair of imaging location and at least two fine stages, both of which are periodically associated with the coarse stage, where each fine stage is configured to support a substrate, the coarse and fine stages configured such that
the fine stages are spaced apart by a distance that enables substrates on both fine stages to be simultaneously imaged at the pair of imaging locations, and
the fine and coarse stages can be moved together over a limited range of movement of the coarse stage to position substrates on both fine stages relative to the pair of imaging locations, and
each of fine stages can be individually moved relative to the coarse stage in a manner that enables the fine stages to be individually repositioned relative to the pair of imaging locations.

12. The substrate handling structure of claim 11, wherein a metrology device is associated with at least one imaging location, the metrology device comprising a pair of metrology components located under the imaging optics at an imaging location, to enable the position of a substrate to be measured relative to the imaging optics, and characterized in that the support member is supported at points on opposite sides of the imaging location.

13. The substrate handling structure of claim 11, further characterized in that the imaging optical system includes imaging optics at an imaging location, and the support member is connected with the imaging optics.

14. The substrate support structure of claim 11, further characterized in that the substrate handling structure comprises a system frame with a portion located below the imaging location, and the support member has a pair of legs on opposite sides of the imaging location, the pair of legs engaging respective portions of the system frame below the imaging location.

15. The substrate support structure of claim 11, further characterized in that the substrate handling structure is configured to allow a stage exchange procedure at an imaging location, and the support member is configured and supported in a manner that avoids interference with a stage exchange procedure at the imaging location.

16. The substrate handling structure of claim 11, wherein the imaging optical system comprises a lithographic imaging optical system.

17. The substrate handling structure of claim 11, wherein at least one loading/unloading coarse stage is provided, for supporting at least one fine stage to be loaded onto the coarse stage, and/or for supporting at least one fine stage to be unloaded from the coarse stage.

18. The substrate handling structure of claim 11, wherein a track is provided for directing at least one fine stage with exposed substrates to an unloading location, and/or for directing at least one fine stage with unexposed substrates to the coarse stage.
